(19) United States
(12) Patent Application Publication
(10) Pub. No.: US 2026/0305388 A1
(43) Pub. Date: Oct. 1, 2026

(54) THERMAL INTERFACE MATERIAL BLEED CONTROL FOR HEAT SPREADERS

(71) Applicant: Intel Corporation, Santa Clara, CA (US)

(72) Inventors: Emilio TARANGO VALLES, Chandler, AZ (US); Sergio Antonio CHAN ARGUEDAS, Chandler, AZ (US); Aravindha ANTONISWAMY, Chandler, AZ (US)

(21) Appl. No.: 19/094,897

(22) Filed: Mar. 29, 2025

(51) Int. Cl. H01L 23/00; H01L 23/367; H01L 23/373; H01L 23/538; H01L 25/065; H01L 25/16

(52) U.S. Cl. CPC H10W 70/60; H10W 40/22; H10W 40/258; H10W 70/611; H10W 90/00; H10W 72/07336; H10W 72/352; H10W 72/387; H10W 90/736

(57) ABSTRACT

Assemblies comprising heat spreaders, a metallic thermal interface material, semiconductor chips, and package substrates are provided wherein the solder interface material has not been reflowed onto a surface of the package substrate.

### FIELD

Descriptions are generally related to semiconductor manufacturing, and more particular descriptions are related to semiconductor device assemblies comprising heat spreaders.

### BACKGROUND

Semiconductor dies are central to intelligent devices and systems, such as personal computers, laptops, tablets, phones, servers, and other consumer and industrial products and systems. Manufacturing semiconductor dies presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Semiconductor device assemblies can include heat spreaders that can also be integrated heat spreaders (IHSs). Heat spreaders typically are useful to dissipate heat generated during the operation of a semiconductor die. A semiconductor die is typically packaged in a manner that protects it from environmental challenges and allows it to connect electrically with other devices. A heat spreader can be coupled to a semiconductor die package through a thermal interface material.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 illustrates a process for assembling semiconductor chip package with a heat spreader.

FIG. 2 provides an additional process for assembling a semiconductor chip package with a heat spreader.

FIG. 3 shows an additional process for assembling a semiconductor chip package with a heat spreader.

FIG. 4 describes a further additional process for assembling a semiconductor chip package with a heat spreader.

FIG. 5 diagrams a process for assembling a semiconductor chip package with a heat spreader.

FIG. 6 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Operations can be performed by semiconductor processing equipment, including robotics and computer systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing and/or testing equipment that is able to perform physical operations such as, for example, solder dispensing, polymer dispensing, material deposition (for example, chemical vapor deposition, atomic layer deposition, physical vapor deposition, electrodeposition, and/or sputtering), chemical mechanical planarization (CMP), and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor die manufacturing processes are sometimes divided into front end of the line (FEOL) processes and back end of the line (BEOL) processes. Electronic circuits and active and passive devices within the die, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the die where interconnects are formed in layers and the feature size of the interconnect increases in layers nearer the surface of the semiconductor die. Interconnects in, for example, semiconductor dies that are integrated into heterogeneous packages (such as, for example, packages that include memory and logic dies), can also include through silicon vias (TSVs) that transverse the semiconductor die device region. Semiconductor devices that have TSVs can blur distinctions between BEOL and FEOL processes.

Semiconductor die interconnects can be created by forming a trench or though-layer via by etching a trench or via structure into a dielectric layer and filling the trench or via with metal. Dielectric layers can comprise, for example, low-κ dielectrics, SiO₂, silicon nitride (SiN), silicon carbide (SiC), and/or silicon carbonitride (SiCN). Low-κ dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric layers that include conductive features can be interlayer dielectric (ILD) features. In general, low-κ dielectrics exhibit a dielectric constant that is less than that of SiO₂.

The terms “package,” “packaging,” “IC package,” or “chip package,” “die package,” “microelectronics package,” “semiconductor die package,” or “semiconductor chip package” are interchangeable and generally refer to an enclosed carrier of one or more dies, in which the dies are coupled to a package substrate and encapsulated. The package substrate provides electrical interconnections between the die(s) and other dies and/or a motherboard or other circuit board for I/O (input/output) communication and power delivery. A package with multiple dies can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass layers.

In further examples of a package substrate core, the substrate core is a glass core comprising one or more solid amorphous glass layers. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, examples of solid amorphous glass substrate cores can be considered to have a rectangular prism volume. The rectangular prism volume can contain vias that have been filled with one or more different materials. A material in a via can be a conductive metal such as copper. Examples of solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example the substrate core can be 10 mm by 10 mm up to 250 mm by 250 mm in two dimensions, but substrate cores do not necessarily have to have the same value in both dimensions.

A package substrate can include one or more interconnect bridges. The interconnect bridge can be partially, fully, or not embedded into the package substrate. An interconnect bridge provides interconnects between dies that are housed on the package substrate. The interconnects can provide signal I/O between the dies. Some interconnect bridges, such as ones that have conductive through-bridge vias, can also provide power to an operably connected die. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The interconnect bridge substrate can comprise, for example, silicon, silicon-on-insulator, float glass, borosilicate glass, silicon dioxide, polymeric, one or more organic polymeric materials, ceramic, and/or a silicon nitride material. The interconnect bridge substrate can comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The interconnect bridge can also include a coreless substrate comprised of a plurality of dielectric layers. The dielectric layers can be, for example, die backside film (DBF), an epoxy film, a B-stage epoxy film, or other dielectric material. Other materials are also possible for interconnect bridge substrates.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T.

Semiconductor die packages are being designed to accommodate increased power demands of the semiconductor die(s). The increased power demands have led to packages that include a significant number of die side capacitors as part of the power delivery design. During assembly process the solder thermal interface material (STIM) used on the package for thermal management, typically bleeds outside of package area where it could touch the capacitors, causing an electrical short and a functional defect on the package. The typical bleed of STIM occurs at a single point on the perimeter of the die, and this location is of a random nature and is typically the location where surface tension is first broken.

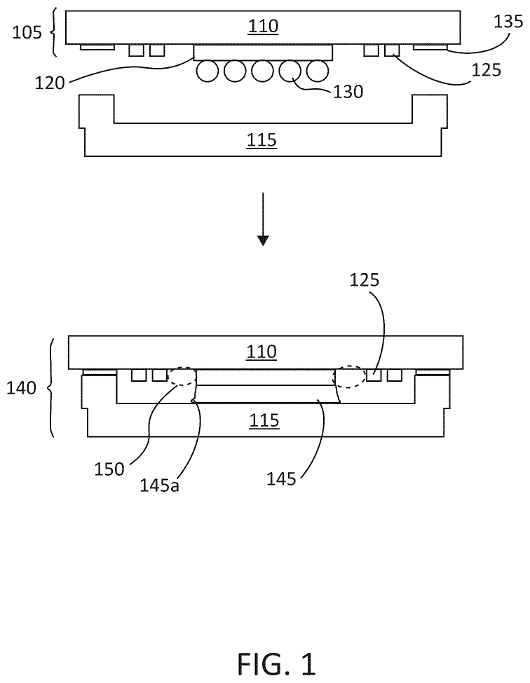

FIG. 1 shows a process for assembling a semiconductor chip package 105 with a heat spreader 115. The semiconductor chip package 105 includes a package substrate 110, a semiconductor chip 120, and capacitors 125. Other components are possible for semiconductor chip packages and a package can contain multiple semiconductor chips. A solder material 130 has been dispensed on the semiconductor chip 120. Although the thermal interface material 130 is in the form of balls in the illustration, other morphologies are possible. For example, the thermal interface material 130 can be in the form of a pre-formed shape that matches the footprint of the semiconductor chip 120, such as a rectangular shape. If the pre-formed shape extends over the edges of the semiconductor chip 120 it is possible that the reflow of the thermal interface material 130 can exhibit a less random and more uniform reflow pattern (e.g., flow region 145a) than if the thermal interface material 130 pre-formed shape does not extend beyond the edges of the semiconductor chip 120. The thermal interface material 130 can be a solder material that comprises tin, indium, nickel, gallium, gold, lead, copper, silver, bismuth, and/or antimony. Example solder materials include, mixtures of tin and bismuth, mixtures of tin, silver, and copper (e.g., Sn-Ag-Cu solders), mixtures of indium and bismuth, mixtures of indium and tin, mixtures of indium, tin, and bismuth, and mixtures of indium and nickel. Other compositions for thermal interface materials are possible, such as materials that are metallic materials and/or are electrically conductive thermal interface materials. The heat spreader 115 can have a different shape than the one pictured. A mounting material 135 can attach the heat spreader 115 to the package substrate 110. The mounting material 135 can be a polymeric adhesive material such as an epoxy or a silicon-based adhesive.

The semiconductor chip package 105 is placed on the heat spreader 115 and the solder material 130 is reflowed creating assembly 140. The solder material 130 can be reflowed through the application of heat. Because the semiconductor chip package 105 is placed on the heat spreader 115 in the orientation shown, gravity has allowed the reflowed solder region 145 to flow against a surface of the heat spreader 115 but not toward the capacitors 125, and not into regions 150 (shown by the oval with dashed lines). Regions 150 can be regions that are free from solder. The reflowed solder material 145 can have a flow region 145a (a bleed) that is spread on a surface of the heat spreader 115.

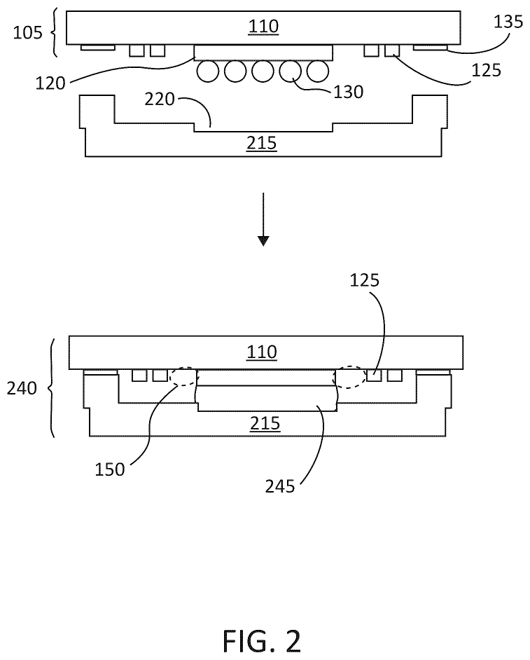

FIG. 2 provides an additional example of process for assembling a semiconductor chip package 105 with a heat spreader 215. Heat spreader 215 comprises a cavity 220 which the reflowed solder material 245 can enter. The opening of the cavity 220 can be same footprint or larger than the footprint semiconductor chip 120 and the opening of the cavity 220 can be aligned with the footprint of the semiconductor chip 120. The semiconductor chip package 105 is placed on the heat spreader 215 and the solder material 130 is reflowed creating assembly 240. Because the semiconductor chip package 105 is placed on the heat spreader 215 in the orientation shown, gravity has allowed the reflowed solder region 245 to flow into the heat spreader cavity 220 but not toward the capacitors 125, and not into regions 150 (shown by the oval with dashed lines).

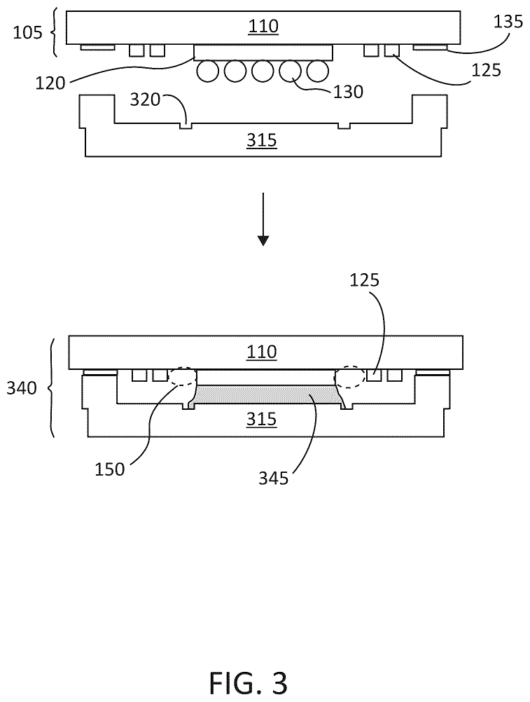

FIG. 3 provides a further example of process for assembling a semiconductor chip package 105 with a heat spreader 315. Heat spreader 315 comprises a trench 320 which the reflowed solder material 345 can enter. The semiconductor chip package 105 is placed on the heat spreader 315 and the solder material 130 is reflowed creating assembly 340. The trench 320 can have a footprint/shape that outlines the shape of four edges of a surface of the semiconductor chip 120, and can be, for example rectangular picture frame in shape. Because the semiconductor chip package 105 is placed on the heat spreader 315 in the orientation shown, gravity has allowed the reflowed solder region 345 to flow into the heat spreader trench 320 but not toward the capacitors 125, and not into regions 150 (shown by the oval with dashed lines).

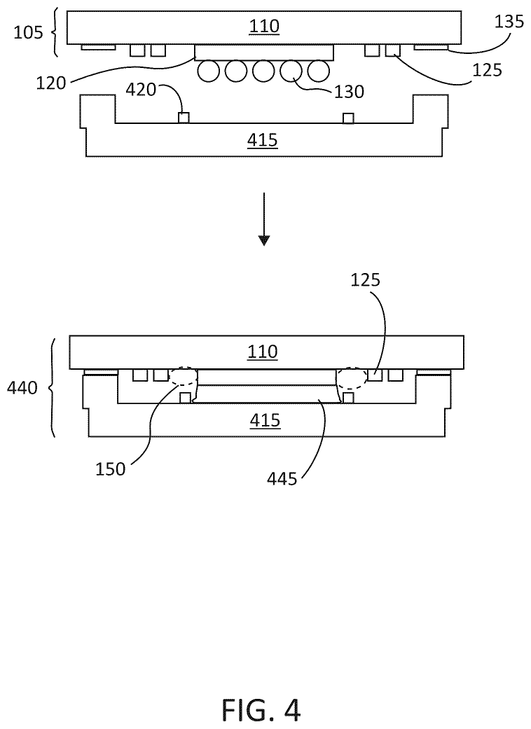

FIG. 4 provides a further additional example of process for assembling a semiconductor chip package 105 with a heat spreader 415. Heat spreader 415 comprises a protuberance 420 which can act as a dam and contain the flow of the reflowed solder material 445. The semiconductor chip package 105 is placed on the heat spreader 415 and the solder material 130 is reflowed creating assembly 440. The protuberance 420 can have a footprint/shape that outlines the shape of four edges of a surface of the semiconductor chip 120, and can be, for example, rectangular picture frame in shape. The protuberance 420 can create a solder containment perimeter. Because the semiconductor chip package 105 is placed on the heat spreader 415 in the orientation shown (in which the top of the page to the bottom of the page represents the direction of gravity's pull), gravity has allowed the reflowed solder region 445 to flow into the heat spreader protuberance 420 but not toward the capacitors 125, and not into regions 150 (shown by the oval with dashed lines). The protuberance 420 can be comprised of, for example, a metal, a polymeric material, such as, a silicon-based polymer, or an epoxy. The polymeric material can be one that was dispensed onto a surface of the heat spreader. The protuberance 420 could be a cold spray material. The protuberance 420 can instead be a metallic feature that was manufactured during the manufacture of the heat spreader. The protuberance 420 could be comprised of copper or nickel.

Where components in FIG. 1 have the same number as in FIGS. 2 and 3, the descriptions for the same-numbered components from FIG. 1 can be used for FIGS. 2 and 3.

The heat spreaders 115, 215, and 315 can be comprised of a metallic material, that can be an alloy and/or that can include one or more layers of material. The heat spreader 115 can be comprised of, for example, copper and/or aluminum, composite materials such as silver and diamond composites and copper and diamond composites, and alloys such as brass alloys, alloys of aluminum, aluminum silicon carbide, and aluminum magnesium alloys. The heat spreader 115 can also comprise layers of materials, such as a first material with one or more other layers of a second and/or third (ect.) material wherein the materials can be any of the foregoing or others. Features such as cavities and trenches in heat spreaders can be made, for example, through a stamping process or through machining. Protuberances 420 can also be made, for example, by dispensing a protuberance material onto a surface of the heat spreader or through a stamping process.

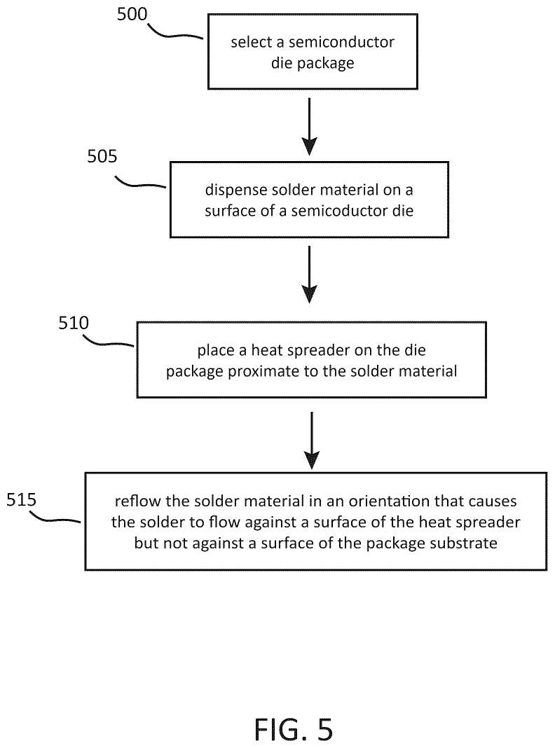

FIG. 5 outlines a method for manufacturing an assembly comprising a heat spreader, a solder thermal interface material, and a semiconductor chip package. A semiconductor chip package is selected for processing 500. The package can contain a plurality of semiconductor chips. Solder material is dispensed on a surface of a semiconductor chip 505. The heat spreader is placed on the package proximate to the solder material 510. The assembly is placed in an orientation that causes the solder material to flow toward the heat spreader during the reflow process 515. This process can be one that is performed using the heat spreaders of FIGS. 1-4, for example.

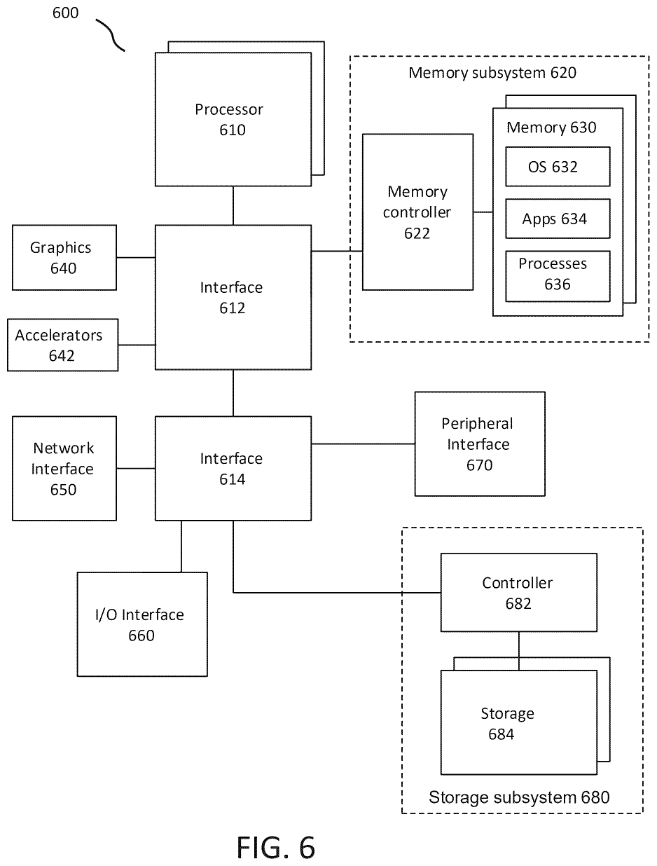

The semiconductor devices (or dies) can be any of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor die packages can be heterogeneous packages that incorporate different types of dies into one package. The semiconductor dies can be any of the dies, for example, described herein with respect to FIG. 6.

FIG. 6 depicts an example computing system. The computing system can be a system used for running equipment in a semiconductor fabrication plant. For example, instructions for operating assembly tools, or for performing one or more aspects of the process described herein can be stored and/or run on the computing system. A computing system 600 can include more, different, or fewer features than the ones described with respect to FIG. 6.

Computing system 600 includes processor 610, which provides processing, operation management, and execution of instructions for system 600. Processor 610 can include any type of microprocessor, CPU (central processing unit), GPU (graphics processing unit), processing core, or other processing hardware to provide processing for system 600, or a combination of processors or processing cores. Processor 610 controls the overall operation of system 600, and can be or include, one or more programmable general-purpose or special-purpose microprocessors, DSPs, programmable controllers, ASICs, programmable logic devices (PLDs), or the like, or a combination of such devices.

In one example, system 600 includes interface 612 coupled to processor 610, which can represent a higher speed interface or a high throughput interface for system components needing higher bandwidth connections, such as memory subsystem 620 or graphics interface components 640, and/or accelerators 642. Interface 612 represents an interface circuit, which can be a standalone component or integrated onto a processor die. Where present, graphics interface 640 interfaces to graphics components for providing a visual display to a user of system 600. In one example, the display can include a touchscreen display.

Accelerators 642 can be a fixed function or programmable offload engine that can be accessed or used by a processor 610. For example, an accelerator among accelerators 642 can provide data compression (DC) capability, cryptography services such as public key encryption (PKE), cipher, hash/authentication capabilities, decryption, or other capabilities or services. In some cases, accelerators 642 can be integrated into a CPU socket (e.g., a connector to a motherboard (or circuit board, printed circuit board, mainboard, system board, or logic board) that includes a CPU and provides an electrical interface with the CPU). For example, accelerators 642 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 642 can provide multiple neural networks, CPUs, processor cores, general purpose graphics processing units, or graphics processing units can be made available for use by artificial intelligence (AI) or machine learning (ML) models.

Memory subsystem 620 represents the main memory of system 600 and provides storage for code to be executed by processor 610, or data values to be used in executing a routine. Memory subsystem 620 can include one or more memory devices 630 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 630 stores and hosts, among other things, operating system (OS) 632 that provides a software platform for execution of instructions in system 600, and stores and hosts applications 634 and processes 636. In one example, memory subsystem 620 includes memory controller 622, which is a memory controller to generate and issue commands to memory 630. The memory controller 622 can be a physical part of processor 610 or a physical part of interface 612. For example, memory controller 622 can be an integrated memory controller, integrated onto a circuit within processor 610.

System 600 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 600 includes interface 614, which can be coupled to interface 612. In one example, interface 614 represents an interface circuit, which can include standalone components and integrated circuitry. In one example, user interface components or peripheral components, or both, couple to interface 614. Network interface 650 provides system 600 the ability to communicate with remote devices (e.g., servers or other computing devices) over one or more networks. Network interface 650 can include an Ethernet adapter, wireless interconnection components, cellular network interconnection components, USB, or other wired or wireless standards-based or proprietary interfaces. Network interface 650 can transmit data to a device that is in the same data center or rack or a remote device, which can include sending data stored in memory.

Some examples of network interface 650 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 600 includes one or more input/output (I/O) interface(s) 660. I/O interface 660 can include one or more interface components through which a user interacts with system 600 (e.g., audio, alphanumeric, tactile/touch, or other interfacing). Peripheral interface 670 can include additional types of hardware interfaces, such as, for example, interfaces to semiconductor fabrication equipment and/or electrostatic charge management devices.

In one example, system 600 includes storage subsystem 680. Storage subsystem 680 includes storage device(s) 684, which can be or include any conventional medium for storing data in a nonvolatile manner, such as one or more magnetic, solid state, and/or optical based disks. Storage 684 can be generically considered to be a “memory,” although memory 630 is typically the executing or operating memory to provide instructions to processor 610. Whereas storage 684 is nonvolatile, memory 630 can include volatile memory (e.g., the value or state of the data is indeterminate if power is interrupted to system 600). In one example, storage subsystem 680 includes controller 682 to interface with storage 684. In one example controller 682 is a physical part of interface 612 or processor 610 or can include circuits or logic in both processor 610 and interface 614.

A power source (not depicted) provides power to the components of system 600. More specifically, power source typically interfaces to one or multiple power supplies in system 600 to provide power to the components of system 600.

Examples of systems may be implemented in various types of computing, smart phones, tablets, personal computers, and networking equipment, such as switches, routers, racks, and blade servers such as those employed in a data center and/or server farm environment.

An assembly can comprise: a semiconductor chip; a package substrate wherein the semiconductor chip is coupled to the package substrate; thermal interface material on a surface of the semiconductor chip wherein the thermal interface material is a metallic material; a heat spreader wherein the heat spreader comprises a cavity and the thermal interface material is in the cavity, wherein the cavity has an opening, wherein opening is same footprint or larger than a footprint of the semiconductor chip, and wherein the opening is aligned with the footprint of the semiconductor chip. The thermal interface material can be reflowed only onto a surface of the heat spreader and not onto a surface of the package substrate. The package substrate can comprise capacitors on a surface of the package substrate. The thermal interface material can be a solder material. The thermal interface material can comprise tin, indium, gallium, gold, lead, copper, silver, bismuth, or antimony. The package substrate can comprise a plurality of semiconductor chips.

An assembly can comprise: a semiconductor chip; a package substrate wherein the semiconductor chip is coupled to the package substrate; thermal interface material on a surface of the semiconductor chip wherein the thermal interface material is a metallic material; a heat spreader wherein the heat spreader comprises a trench, wherein the thermal interface material is in the trench, wherein the trench has a picture frame shape, wherein the picture frame shape aligns with edges of the semiconductor chip. The thermal interface material can be reflowed only onto a surface of the heat spreader and not onto a surface of the package substrate. The package substrate can comprise capacitors on a surface of the package substrate. The thermal interface material can comprise tin, indium, gallium, gold, nickel, lead, copper, silver, bismuth, or antimony. The package substrate can comprise a plurality of semiconductor chips.

An assembly can comprise: a semiconductor chip; a package substrate wherein the semiconductor chip is coupled to the package substrate; thermal interface material on a surface of the semiconductor chip wherein the thermal interface material is a metallic material; a heat spreader wherein the heat spreader comprises a protuberance, wherein the thermal interface material is within a region outlined by the protuberance, wherein the protuberance has a picture frame shape, wherein the picture frame shape aligns with edges of the semiconductor chip. The thermal interface material can be reflowed only onto a surface of the heat spreader and not onto a surface of the package substrate. The package substrate can comprise capacitors on a surface of the package substrate. The thermal interface material can comprise tin, indium, gallium, gold, nickel, lead, copper, silver, bismuth, or antimony. The package substrate can comprise a plurality of semiconductor chips. The protuberance can comprise a polymeric material.

Besides what is described herein, various modifications can be made to what is disclosed and implementations without departing from their scope. Therefore, the illustrations and examples herein should be construed in an illustrative, and not a restrictive sense.

What is claimed is:

1. An assembly comprising:
a semiconductor chip;
a package substrate wherein the semiconductor chip is coupled to the package substrate;
thermal interface material on a surface of the semiconductor chip wherein the thermal interface material is a metallic material;
a heat spreader wherein the heat spreader comprises a cavity and the thermal interface material is in the cavity, wherein the cavity has an opening, wherein opening is same footprint or larger than a footprint of the semiconductor chip, and wherein the opening is aligned with the footprint of the semiconductor chip.

2. The assembly of claim 1 wherein the thermal interface material is reflowed only onto a surface of the heat spreader and not onto a surface of the package substrate.

3. The assembly of claim 1 wherein the package substrate comprises capacitors on a surface of the package substrate.

4. The assembly of claim 1 wherein the thermal interface material is a solder material.

5. The assembly of claim 1 wherein the thermal interface material comprises tin, indium, gallium, gold, nickel, lead, copper, silver, bismuth, or antimony.

6. The assembly of claim 1 wherein the package substrate comprises a plurality of semiconductor chips.

7. An assembly comprising:
a semiconductor chip;
a package substrate wherein the semiconductor chip is coupled to the package substrate;
thermal interface material on a surface of the semiconductor chip wherein the thermal interface material is a metallic material;
a heat spreader wherein the heat spreader comprises a trench, wherein the thermal interface material is in the trench, wherein the trench has a picture frame shape, wherein the picture frame shape aligns with edges of the semiconductor chip.

8. The assembly of claim 7 wherein the thermal interface material is reflowed only onto a surface of the heat spreader and not onto a surface of the package substrate.

9. The assembly of claim 7 wherein the package substrate comprises capacitors on a surface of the package substrate.

10. The assembly of claim 7 wherein the thermal interface material is a solder material.

11. The assembly of claim 7 wherein the thermal interface material comprises tin, indium, gallium, gold, nickel, lead, copper, silver, bismuth, or antimony.

12. The assembly of claim 7 wherein the package substrate comprises a plurality of semiconductor chips.

13. An assembly comprising:
a semiconductor chip;
a package substrate wherein the semiconductor chip is coupled to the package substrate;
thermal interface material on a surface of the semiconductor chip wherein the thermal interface material is a metallic material;
a heat spreader wherein the heat spreader comprises a protuberance, wherein the thermal interface material is within a region outlined by the protuberance, wherein the protuberance has a picture frame shape, wherein the picture frame shape aligns with edges of the semiconductor chip.

14. The assembly of claim 13 wherein the thermal interface material is reflowed only onto a surface of the heat spreader and not onto a surface of the package substrate.

15. The assembly of claim 13 wherein the package substrate comprises capacitors on a surface of the package substrate.

16. The assembly of claim 13 wherein the thermal interface material is a solder material.

17. The assembly of claim 13 wherein the thermal interface material comprises tin, indium, gallium, gold, nickel, lead, copper, silver, bismuth, or antimony.

18. The assembly of claim 13 wherein the package substrate comprises a plurality of semiconductor chips.

19. The assembly of claim 13 wherein the protuberance comprises a polymeric material.
